(19) United States
(12) Patent Application Publication
(10) Pub. No.: US 2010/0050044 A1
(43) Pub. Date: Feb. 25, 2010

(54) RADIO COMMUNICATION APPARATUS AND TEMPORARY BIT INSERTION METHOD

(75) Inventors: Kenichi Kuri, Kanagawa (JP); Akihiko Nishio, Kanagawa (JP); Masaru Fukuoka, Ishikawa (JP)

Correspondence Address: Dickinson Wright PLLC;James E. Ledbetter, Esq., International Square, 1875 Eye Street, N.W., Suite 1200, Washington, DC, 20006, US

(73) Assignee: PANASONIC CORPORATION, Osaka (JP)

(21) Appl. No.: 12/523,945

(22) PCT Filed: Jan. 22, 2008
(86) PCT No.: PCT/JP2008/050810

§ 371 Date: Jul. 21, 2009

(30) Foreign Application Priority Data
Jan. 23, 2007 (JP) 2007-012676

(51) Int. Cl. H03M 13/05; G06F 11/10

(52) U.S. Cl. 714/752; 714/E11.032

(57) ABSTRACT

Provided is a radio communication apparatus capable of always obtaining the optimum error rate characteristic when an LDPC code is used for an error-correcting code. In the apparatus, a temporary bit insertion section (101) inserts a temporary bit into a position equivalent to that of the systematic bit corresponding to a variable node having the largest number of connections with a check node in the Tanner graph corresponding to a check matrix in a transmission bit string and outputs the generated bit string to an LDPC coding section (102), The LDPC coding section (102) performs LDPC coding on the bit string inputted from the temporary bit insertion section (101) by using the check matrix and obtains an LDPC code word composed of the systematic bit and a parity bit. The LDPC code word is outputted to a temporary bit removal section (103).

### TECHNICAL FIELD

The present invention relates to a radio communication apparatus and a temporary bit inserting method.

### BACKGROUND ART

In recent years, multimedia communication such as data communication and video streaming has continued to increase in popularity. Therefore, data sizes are expected to increase even more in the future, and growing demands for higher-speed data rates for mobile communication services are also anticipated.

To realize future ultra high speed transmission, an LDPC (Low-Density Parity-Check) code has attracted attention as an error correcting code. Use of an LDPC code as an error correcting code enables decoding processing to be parallelized, allowing decoding processing to be speeded up compared with the use of a turbo code that requires iterative serial execution of decoding processing.

LDPC encoding is performed using a parity check matrix where a large number of 0s and a small number of 1s are arranged. A radio communication apparatus of the transmitting side encodes a transmission bit sequence using a parity check matrix, to obtain an LDPC codeword composed of systematic bits and parity bits. A radio communication apparatus of the receiving side decodes received data by iteratively executing passing of the likelihoods of individual bits between the parity check matrix row direction and the parity check matrix column direction, to acquire a received bit sequence. Here, the number of is contained in each column in a parity check matrix is called the column degree, and the number of 1s contained in each row in a parity check matrix is called the row degree. A parity check matrix can be represented by a Tanner graph, which is a two-part graph composed of rows and columns. In a Tanner graph, each row of a parity check matrix is called a check node, and each column of a parity check matrix is called a variable node. Variable nodes and check nodes of a Tanner graph are connected in accordance with the arrangement of is in the parity check matrix, and a radio communication apparatus of the receiving side decodes received data by iteratively executing passing of likelihoods between connected nodes, to obtain a received bit sequence.

A method of setting a lower coding rate than a coding rate of the LDPC code (hereinafter referred to as “mother coding rate”) is the shortened method. The shortened method is a technique of inserting temporary bits, which are known between a radio communication apparatus of the transmitting side and a radio communication apparatus of the receiving side, in a transmission bit sequence and encoding the transmission bit sequence, and removing the temporary bits from the resulting codeword. This enables a lower coding rate than the mother coding rate to be set.

As a conventional technique of the shortened method for the LDPC codeword, inserting temporary bits in the beginning of a transmission bit sequence is studied (see Non-patent Document 1).

Non-patent Document 1: R1-0060499, “Structured LDPC coding with rate matching,” ZTE, 3GPP TSG RAN WG1 #44 Meeting, contribution, 2006/02

### DISCLOSURE OF INVENTION

### Problems to be Solved by the Invention

In LDPC encoding, error rate performances vary according to the number of connections with check nodes in variable nodes. Therefore, as a conventional technique described above, if temporary bits are inserted simply in the beginning of a transmission bit sequence without taking into consideration of that number of connections, it may not be possible to provide the optimum error rate performances.

It is therefore an object of the present invention to provide a radio communication apparatus and a temporary bit inserting method that can provide the optimum error rate performances constantly when LDPC codes are used in error correcting codes.

### Means for Solving the Problem

The radio communication apparatus of the present invention provides a radio communication apparatus of the transmitting side that performs low density parity check encoding using a parity check matrix and adopts the configuration including: an inserting section that inserts, in a first bit sequence, a temporary bit in a same position as a systematic bit position corresponding to a variable node having a largest number of connections with check nodes in a Tanner graph that corresponds to the parity check matrix, to generate a second bit sequence; an encoding section that performs low density parity check encoding using the parity check matrix for the second bit sequence, to acquire a codeword composed of a systematic bit and a party bit; and a removing section that removes the temporary bit in the codeword.

### ADVANTAGEOUS EFFECT OF THE INVENTION

According to the present invention, it is possible to provide the optimum error rate performances constantly when LDPC codes are used in error correcting codes.

### BRIEF DESCRIPTION OF DRAWINGS

FIG. 1 is a block diagram showing a configuration of the radio communication apparatus of the transmitting side according to Embodiment 1 of the present invention;

FIG. 2 is a parity check matrix according to Embodiment 1 of the present invention;

FIG. 3 is a Tanner graph according to Embodiment 1 of the present invention;

FIG. 4 illustrates temporary bit inserting processing according to Embodiment 1 of the present invention;

FIG. 5 is a block diagram showing a configuration of the radio communication apparatus of the receiving side according to Embodiment 1 of the present invention;

FIG. 6 illustrates padding processing according to Embodiment 1 of the present invention;

FIG. 7 shows combinations of the variable nodes according to Embodiment 2 of the present invention;

FIG. 8 shows temporary bit inserting processing according to Embodiment 2 of the present invention; and

FIG. 9 shows the combinations of the variable nodes according to Embodiment 2 of the present invention.

### BEST MODE FOR CARRYING OUT THE INVENTION

Now, embodiments of the present invention will be described in detail with reference to the accompanying drawings.

In the following description, amongst the columns of a parity check matrix or variable nodes in a Tanner graph, parts corresponding to systematic bits will be called “systematic bit positions.”

### Embodiment 1

In the present embodiment, in a transmission bit sequence, a temporary bit is inserted in the same position as the systematic bit position corresponding to the variable node having the largest number of connections with check nodes in a Tanner graph that corresponds to a parity check matrix. A case will be explained here where one temporary bit is inserted.

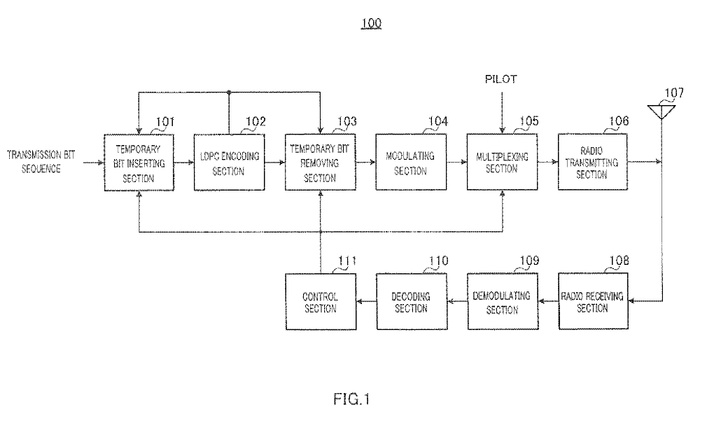

FIG. 1 shows the configuration of radio communication apparatus 100 of the transmitting side according to the present embodiment.

In radio communication apparatus 100 of the transmitting side, temporary bit inserting section 101 receives a transmission bit sequence as input. Further, temporary bit inserting section 101 receives a parity check matrix for an LDPC code from LDPC encoding section 102. Temporary bit inserting section 101 inserts a temporary bit in the transmitting bit sequence based on the parity check matrix and outputs the generated bit sequence to LDPC encoding section 102. Further, the number of temporary bits to insert is determined based on the difference between the coding rate in LDPC encoding section 102 (i.e. the mother coding rate) and the coding rate set up from control section 111 (i.e. the coding rate of LDPC codewords after the temporary bits are removed). To be more specific, the number of temporary bits to insert is determined by N((Rₘ−R)/(1−R)). Here, N represents the LDPC codeword length, Rₘ represents the mother coding rate and R represents the coding rate received as input from control section 111. The temporary bit inserting processing in temporary bit inserting section 101 will be described later in detail. LDPC encoding section 102 performs LDPC encoding on the bit sequence received as input from temporary bit inserting section 101 using a parity check matrix to acquire an LDPC codeword formed with systematic bits and parity bits. This LDPC code word is outputted to temporary bit removing section 103. Further, LDPC encoding section 102 outputs a parity check matrix to temporary bit inserting section 101 and temporary bit removing section 103.

Temporary bit removing section 103 removes the temporary bit from the LDPC codeword based on the parity check matrix, and outputs the LDPC codeword without the temporary bit to modulating section 104. Temporary bit removing section 103 identifies the positions and the number of temporary bits to remove in the same method as in temporary bit inserting section 101.

Modulating section 104 generates data symbols by modulating the LDPC codeword without the temporary bit, and outputs the generated data symbols to multiplexing section 105.

Multiplexing section 105 multiplexes the data symbols, pilot signals and control signals received as input from control section 111, and output the generated multiplexed signal to radio transmitting section 106.

Radio transmitting section 106 performs transmission processing including D/A conversion, amplification and up-conversion on the multiplexed signal, and transmits the signal after transmission processing to a radio communication apparatus of the receiving side from antenna 107.

Meanwhile, radio receiving section 108 receives the control signal transmitted from the radio communication apparatus of the receiving side through antenna 107, performs reception processing such as down-conversion and A/D conversion on the control signal and outputs the control signal, to demodulating section 109. This control signal includes a CQI (Channel Quality Indicator) generated in the radio communication apparatus of the receiving side.

Demodulating section 109 demodulates the control signal and outputs the demodulated signal to decoding section 110.

Decoding section 110 decodes the control signal and outputs the CQI included in the control signal to control section 111.

Control section 111 controls the coding rate of the LDPC codeword after the temporary bits are removed according to the CQI. Control section 111 determines a coding rate corresponding to the CQI received as input, and outputs a control signal showing the determined coding rate to temporary bit inserting section 101, temporary bit removing section 103 and multiplexing section 105. When the CQI received as input corresponds to lower channel quality, control section 111 determines the coding rate of the LDPC codeword after the temporary bits are removed to be a lower coding rate.

Next, the temporary bit inserting processing in temporary bit inserting section 101 will be described.

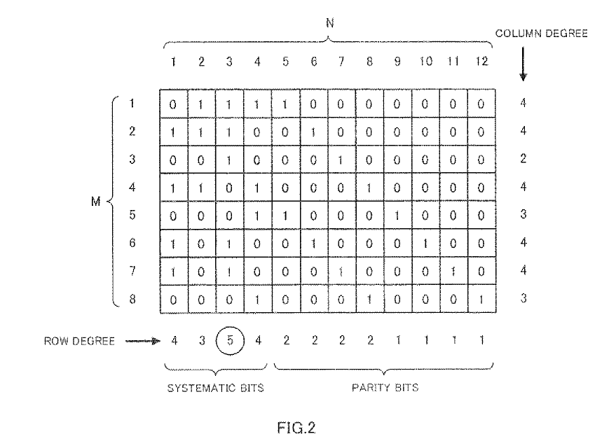

FIG. 2 shows an 8×12 parity check matrix as an example. As shown here, a parity check matrix is represented by a M×N matrix and is composed of 0s and 1s.

Each column in a parity check matrix corresponds to codeword bits in the LDPC codeword. That is, when LDPC encoding is performed using the parity check matrix shown in FIG. 2, a 12-bit LDPC codeword is acquired.

Further, in the parity check matrix shown in FIG. 2, the column degree of the first column is the number of is in the first column, that is, four, and the column degree of the second column is the number of 1s in the second column, that is, three. The same will apply to the third column to the twelfth column.

Therefore, in the 12-bit LDPC codeword, the column degree of the first bit is four and the column degree of the second bit is three. The same will apply to the third column to twelfth column.

Likewise, in the parity check matrix shown in FIG. 2, the row degree of the first row is the number of 1s in the first row, that is, four, and the row degree of the second row is the number of 1s in the second row, that is, four. The same will apply to the third to the eighth rows.

Furthermore, the parity check matrix shown in FIG. 2 can be represented by a Tanner graph composed of the rows and columns of the parity check matrix.

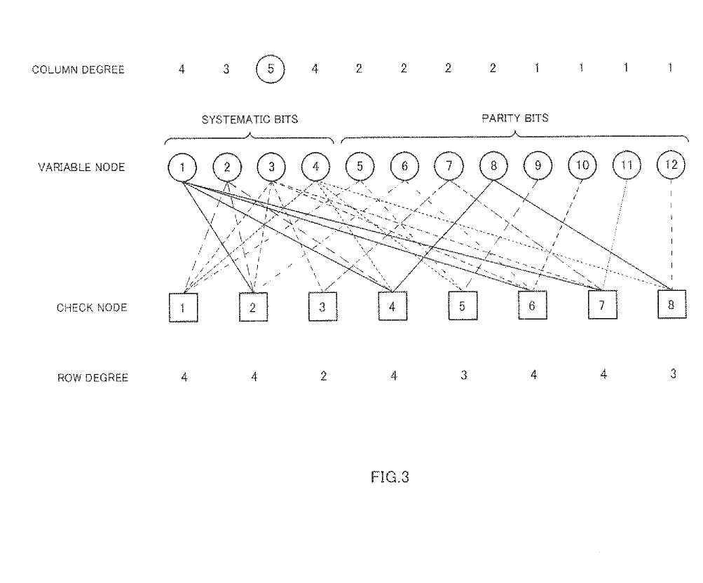

FIG. 3 shows a Tanner graph corresponding to the parity check matrix in FIG. 2. The Tanner graph is composed of check nodes corresponding to the rows of the parity check matrix and variable nodes corresponding to the columns of the parity check matrix. That is, the Tanner graph corresponding to an 8×12 parity check matrix is a two part graph composed of eight check nodes and twelve variable nodes.

Furthermore, variable nodes in the Tanner graph correspond to codeword bits in the LDPC codeword.

Here, the variable nodes and check nodes in the Tanner graph are connected in accordance with the arrangement of “1”s in the parity check matrix.

Specifically, explanation will be given based on the variable nodes. Variable node 1 in the Tanner graph shown in FIG. 3 corresponds to the first column (N−1) of the parity check matrix shown in FIG. 2. The column degree of the first column of the parity check matrix is four, and the rows in which a 1 is located in the first column are the second row, the fourth row, the sixth row and the seventh row. Therefore, there are four connections at variable node 1, that is, check node 2, check node 4, check node 6 and check node 7. Likewise, variable node 2 in the Tanner graph corresponds to the second column (N=2) of the parity check matrix. The column degree of the second column of the parity check matrix is three, and the rows in which a 1 is located in the second column are the first row, the second row and the fourth row. Therefore, there are three connections at variable node 2, that is, check node 1, check node 2 and check node 4. The same will apply to variable node 3 to variable node 12.

Similarly, to give a concrete description based on check nodes, check node 1 of the Tanner graph shown in FIG. 3 corresponds to the first row (M=1) of the parity check matrix shown in FIG. 2. The row degree of the first row of the parity check matrix is four, and the columns in which a 1 is located in the first row are the second column, the third column, the fourth column and the fifth column. Consequently, there are four connections at check node 1, that is, variable node 2, variable node 3, variable node 4 and variable node 5. Likewise, check node 2 in the Tanner graph corresponds to the second row (M=2) of the parity check matrix. The row degree of the second row of the parity check matrix is tour, and the column in which a 1 is located in the second row is the first column, the second column, the third column and the sixth column. Therefore, there are four connections at check node 2, that is, for variable node 1, variable node 2, variable node 3 and variable node 6. The same applies to check node 3 to check node 8.

In this way, in a Tanner graph, the variable nodes and check nodes are connected in accordance with the arrangement of is in a parity check matrix. That is, the number of check nodes connected to each variable node in a Tanner graph equals the column degree of a column in a parity check matrix. Also, the check nodes with which each variable node is connected in a Tanner graph are the check nodes corresponding to the rows in which is are located in the columns in a parity check matrix. Similarly, the number of variable nodes connected to each check node in a Tanner graph equals the row degree of a row in a parity check matrix. Also, the variable nodes with which each check node is connected in a Tanner graph are the variable nodes corresponding to the columns in which 1s are located in the rows in a parity check matrix.

The radio communication apparatus of the receiving side passes likelihoods between the variable nodes, through the check nodes, and decodes received data by iteratively updating the likelihoods of the variable nodes. By this means, the number of times to pass likelihoods to other variable nodes increases when a variable node has a larger number of connections with check nodes (i.e. variable nodes having a larger column degree). Further, if the likelihood of that variable node is higher, the effect of updating the likelihoods of the check nodes with which that variable node is connected improves.

Then, in the case where one temporary bit is inserted, in a transmission bit sequence, temporary bit inserting section 101 inserts a temporary bit in the same position as the systematic bit position corresponding to the variable node having the largest number of connections with check nodes (i.e. variable node having the largest column degree).

Now, a specific explanation will be given as follows. In the following description, the mother coding rate Rₘ is ⅓, and the coding rate K determined in control section 111 is 3/11. Further, temporary bit inserting section 101 finds the number of temporary bits to be inserted from N((Rₘ−R)/(1−R)) and inserts one temporary bit. Consequently, when LDPC encoding is performed on a 4-bit sequence in which one temporary bit is inserted in a 3-bit transmission sequence using the parity check matrix shown in FIG. 2, a 12-bit LDPC codeword composed of four systematic bits and eight parity bits is acquired.

As described above, in a transmission bit sequence, temporary bit inserting section 101 inserts a temporary bit in the same position as the systematic bit position corresponding to the variable node having the largest number of connections with check nodes (i.e. the variable node having the largest column degree).

First, temporary bit inserting section 101 compares the number of connections with check nodes in variable node 1 to variable node 4 (i.e. the first column to the fourth column in the parity check matrix shown in FIG. 2) corresponding to the systematic bits in the Tanner graph shown in FIG. 3. That is, temporary bit inserting section 101 compares the number of connections with check nodes at variable node 1 (column degree 4 of the first column), which is four, the number of connections with check nodes at variable node 2 (column degree 3 of the second column), which is three, the number of connections with check nodes at variable node 3 (column degrees of the third column), which is five and the number of connections with check nodes at variable node 4 (column degree 4 of the fourth column), which is four.

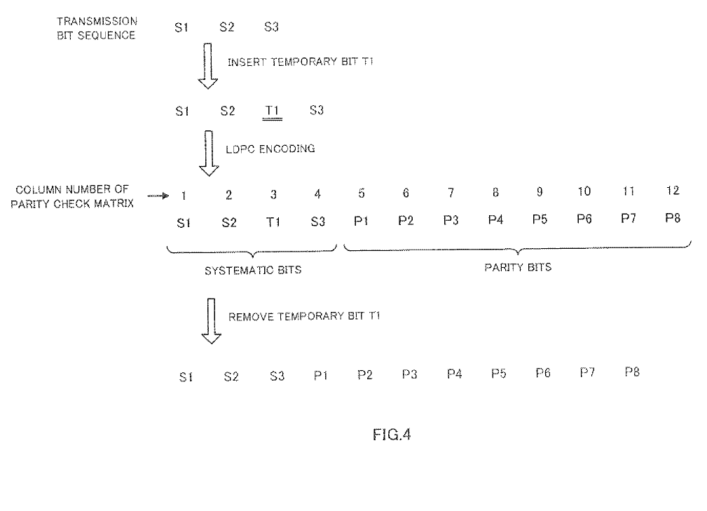

Then, as shown in FIG. 4, temporary bit inserting section 101 inserts temporary bit T1 in the same position as the systematic bit position corresponding to variable node 3 (the third column) having the largest number of connections with check nodes, which is five, that is, inserts temporary bit T1 between the second bit S2 and the third bit S3 in a 3-bit transmission sequence S1, 52 and S3. By this means, temporary bit inserting section 101 can acquire a 4-bit transmission sequence S1, S2, T1 and S3, which is subject to LDPC encoding. Then, in LDPC encoding section 102, LDPC encoding is performed on a 4-bit sequence S1, S2, T1 and S3, and a 12-bit LDPC codeword composed of four systematic bits of S1, S2, T1 and S3 and eight parity bits of P1 to P8 is acquired. Further, in temporary bit removing section 103, temporary bit T1 is removed from the 12-bit LDPC codeword and an 11-bit LDPC codeword is acquired.

In this way, according to the present embodiment, in the case where one temporary bit is inserted, in a transmission bit sequence, a temporary bit is inserted in the same position as the systematic bit position corresponding to the variable node having the largest number of connections with check nodes. For the reason, it is possible to pass the high likelihood that the temporary bit known between the radio communication apparatus of the transmitting side and the radio communication apparatus of the receiving side has, to a large number of check nodes, so that it is possible to perform LDPC encoding providing optimum error rate performances constantly.

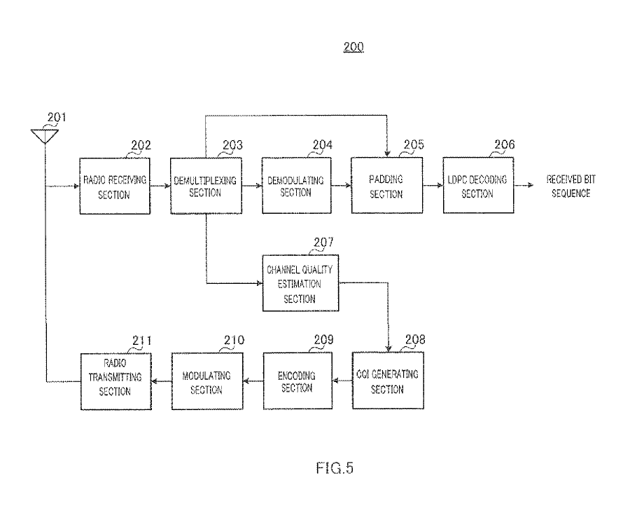

Next, the radio communication apparatus of the receiving side according to the present embodiment will be described. FIG. 5 shows the configuration of radio communication apparatus 200 of the receiving side according to the present embodiment.

In radio communication apparatus 200 of the receiving side, radio receiving section 202 receives a multiplexed signal transmitted from radio communication apparatus 100 (FIG. 1) of the transmitting side through antenna 201, performs reception processing including down-conversion and A/D conversion on the received signal and outputs the signal subjected to reception processing to demultiplexing section 203. This received signal includes data symbols, pilot signals and control signals designating coding rates determined in radio communication apparatus 100 of the transmitting side.

Demultiplexing section 203 demultiplexes the received signal into the data symbols, the pilot signals and the control signals. Further, demultiplexing section 203 outputs the data symbols to demodulating section 204, the pilot signals to channel quality estimation section 207 and the control signals to padding section 205.

Demodulating section 204 demodulates the data symbols to acquire received data and outputs the received data to padding section 205.

In the received data, padding section 205 pads a temporary bit and outputs the acquired received data to LDPC decoding section 206. Further, the number of temporary bits to pad is determined based on the difference between the coding rate in LDPC decoding section 206, that is, the coding rate Rₘ in LDPC encoding section 102 (FIG. 1) (i.e. the mother coding rate) and the coding rate R shown by the control signal received as input from demultiplexing section 203 (i.e. coding rate determined in control section 111 (FIG. 1)). To be more specific, the number of temporary bits to pad is determined by Nᵣ((Rₘ−R)/(1−Rₘ)). Here, Nᵣ represents the data length of received data. That is, the number of temporary bits to pad equals the number of temporary bits to insert in radio communication apparatus 100 (FIG. 1) of the transmitting side. The padding processing in padding section 205 will be described later in detail.

LDPC decoding section 206 performs LDPC decoding on the received data received as input from padding section 205 to acquire a received bit sequence, using the same parity check matrix as the parity check matrix used in LDPC encoding section 102 (FIG. 1).

Meanwhile, channel quality estimation section 207 estimates channel quality using the pilot signal received as input from demultiplexing section 203. Here, channel quality estimation section 207 estimates the SINR (Signal to Interference and Noise Ratio) of the pilot signal as channel quality, and outputs the estimated SINR to CQI generating section 208.

CQI generating section 208 generates a CQI corresponding to the SINR received as input, and outputs the generated CQI to encoding section 209.

Encoding section 209 encodes the CQI and outputs the CQI after encoding to modulating section 210.

Modulating section 210 modulates the CQI to generate a control signal, and outputs the generated control signal to radio transmitting section 211. Radio transmitting section 211 performs transmission processing including D/A conversion, amplification and up-conversion on the control signal and transmits the signal after transmission processing to radio communication apparatus 100 (FIG. 1) of the transmitting side from antenna 201.

Next, the padding processing in padding section 205 will be described in detail.

Similar to temporary bit inserting section 101 (FIG. 1) of radio communication apparatus 100 of the transmitting side, in the received data, padding section 205 pads a temporary bit in the same position as the systematic bit position corresponding to the variable node having the largest number of connections with check nodes (i.e. the variable node having the largest column degree) in the Tanner graph.

Here, received data length Nᵣ has 11 bits, so that padding section 205 determines the number of temporary bits to pad from Nᵣ((Rₘ−R)/(1−R)) and pads one temporary bit.

Similar to temporary bit inserting section 101 (FIG. 1) of radio communication apparatus 100 of the transmitting side, padding section 205 first compares the number of connections with check nodes in variable node 1 to variable node 4 (i.e. the first column to the fourth column in the parity check matrix shown in FIG. 2) corresponding to the systematic bits in the Tanner graph shown in FIG. 3. That is, padding section 205 compares the number of connections with check nodes at variable node 1 (column degree 4 of the first column), which is four, the number of connections with check nodes at variable node 2 (column degree 3 of the second column), which is three, the number of connections with check nodes at variable node 3 (column degree 5 of the third column)/which is five, and the number of connections with check nodes at variable node 4 (column degree 4 of the fourth column), which is four.

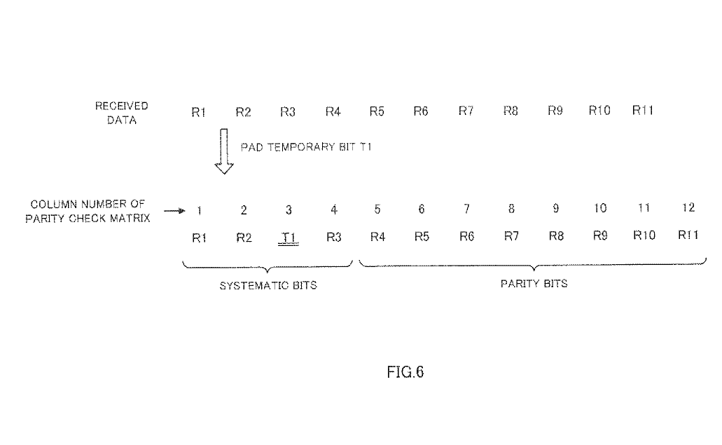

Then, as shown in FIG. 6, padding section 205 pads temporary bit T1 in the same position as the systematic bit position corresponding to variable node 3 (third column) having the largest number of connections with check nodes, which is five, that is, pads temporary bit T1 between the second bit R2 and the third bit R3 in an 11-bit received data composed of bits R1 to R11. By this means R3 is shifted by one bit and arranged in the fourth bit. Likewise, R4 to R11 are shifted by one bit each. Here, the systematic bit position in which a temporary bit is padded and the systematic bit position in which a temporary bit is inserted in radio communication apparatus 100 (FIG. 1) of the transmitting side are identical.

In this way, padding section 205 specifies the systematic bit position to pad a temporary bit based on the same parity check matrix as used in temporary bit inserting section 101 in radio communication apparatus 100. By this means, even when radio communication apparatus 100 of the transmitting side does not report the systematic bit position in which a temporary bit is inserted in radio communication apparatus 100 of the transmitting side, padding section 205 can acquire 12-bit data having the same data length as the LDPC codeword generated in radio communication apparatus 100 of the transmitting side (i.e. received data after padding).

In this way, according to the present embodiment, in received data, a temporary bit is padded in the same position as the systematic bit position corresponding to the variable node having the largest number of connections with check nodes, so that it is possible to pass high likelihoods to a large number of variable nodes and perform LDPC decoding on the received data. Consequently, it is possible to provide optimum error rate performances constantly.

Further, according to the present embodiment, the radio communication apparatus of the receiving side is able to specify the systematic bit position to pad a temporary bit even when the radio communication apparatus of the transmitting side does not report the systematic bit position in which the temporary bit is inserted, and therefore the radio communication apparatus of the receiving side is able to perform LDPC decoding that provides optimum error rate performances constantly without increasing overhead with report information.

### Embodiment 2

Although a case has been explained with Embodiment 1 where one temporary bit is inserted, a case will be explained with Embodiment 2 where a plurality of temporary bits are inserted.

Now, the operations of temporary bit inserting section 101 according to the present embodiment will be explained below. Further, a case will be explained here where two temporary bits are inserted.

In a transmission bit sequence, temporary bit inserting section 101 inserts a plurality of temporary bits in the same positions as the plurality of systematic bit positions corresponding to the variable nodes belonging to the combination having the largest number of connections with a plurality of different check nodes amongst a plurality of combinations of variable nodes.

A specific example of the temporary bit inserting method will be described.

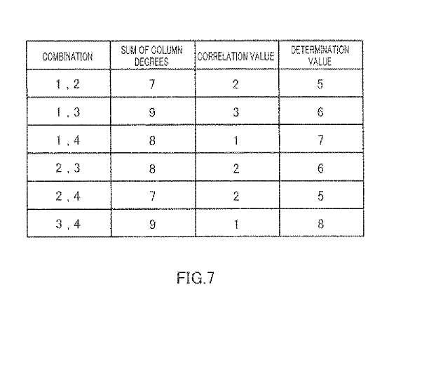

First, in all combinations of extracting two variable nodes from four variable nodes (i.e. variable node 1 to variable node 4) corresponding to systematic bits in the Tanner graph shown in FIG. 3, temporary bit inserting section 101 calculates the sum of number of connections variable nodes belonging to the combinations hold with check nodes. That is, temporary bit inserting section 101 calculates the sum of the column degrees of the variable nodes belonging to each combination. In the Tanner graph shown in FIG. 3, the column degree of variable node 1 is four, and the column degree of variable node 2 is three, so that the sum of the column degrees of the combination of variable node 1 and variable node 2 (i.e. 1, 2) is seven, as shown in FIG. 7. Further, the column degree of variable node 3 is five in the Tanner graph shown in FIG. 3, so that the sum of the column degrees of the combination of variable node 1 and variable node 3 (i.e. 1, 3) is nine, as shown in FIG. 7. Likewise, the sum of the column degrees of the combination of variable node 1 and variable node 4 (i.e. 1, 4) is eight, the sum of the column degrees of combination of variable node 2 and variable node 3 (i.e. 2, 3) is eight, the sum of the column degrees of the combination of variable node 2 and variable node 4 (i.e. 2, 4) is seven and the sum of the column degrees of the combination of variable node 3 and variable node 4 (i.e. 3, 4) is nine.

Next, temporary bit inserting section 101 finds the number of overlapping connections variable nodes in a combination hold with the same check nodes (hereinafter “correlation value”). The correlation value equals the number of rows in which is are located in the same row between variable nodes in the parity check matrix shown in FIG. 2. In the Tanner graph shown in FIG. 3, variable node 1 and variable node 2 have overlapping connection with two check nodes of check node 2 and check node 4, so that the correlation value of the combination (1, 2) is two as shown in FIG. 7. Further, in the Tanner graph shown in FIG. 3, variable node 1 and variable node 3 have overlapping connection with three check nodes of check node 2, check node 6 and check node 7, so that the correlation value of the combination (1, 3) is three, as shown in FIG. 7. Likewise, the correlation value of the combination (1, 4) is one, the correlation value of the combination (2, 3) is two, the correlation value of the combination (2, 4) is two and the correlation value of the combination (3, 4) is one.

Further, temporary bit inserting section 101 finds the difference (hereinafter “determination value”) between the sum of the column degrees in each combination and the correlation value. This determination value is the value subtracting the number of overlapping connections variable nodes hold with check nodes from the sum of the number of connections variable nodes belonging to a combination hold with check nodes. That is, this determination value represents the number of connections with a plurality of different check nodes in each combination. As shown in FIG. 7, the sum of the column degrees in the combination (1, 2) is seven and the correlation value is two, so that the determination value is five. That is, in the Tanner graph shown in FIG. 3, variable node 1 and variable node 2 are connected with five different check nodes, that is, check node 1, check node 2, check node 4, check node 6 and check node 7 in the combination (1, 2). Further, as shown in FIG. 7, the sum of the column degree is nine and the correlation value is three in the combination (1, 3), so that the determination value is six. That is, in the Tanner graph shown in FIG. 3, variable node 1 and variable node 3 are connected with six different check nodes, that is, check node 1, check node 2, check node 3, check node 4, check node 6 and check node 7 in the combination (1, 3). Likewise, the determination value of the combination (1, 4) is seven, determination value of the combination (2, 3) is six, the determination value of the combination (2, 4) is five and the determination value of the combination (3, 4) is eight. Here, the number of all check nodes is 8 in the Tanner graph shown in FIG. 3, so that all check nodes are connected from variable node 3 and variable node 4 in the combination (3, 4), whose determination value is eight.

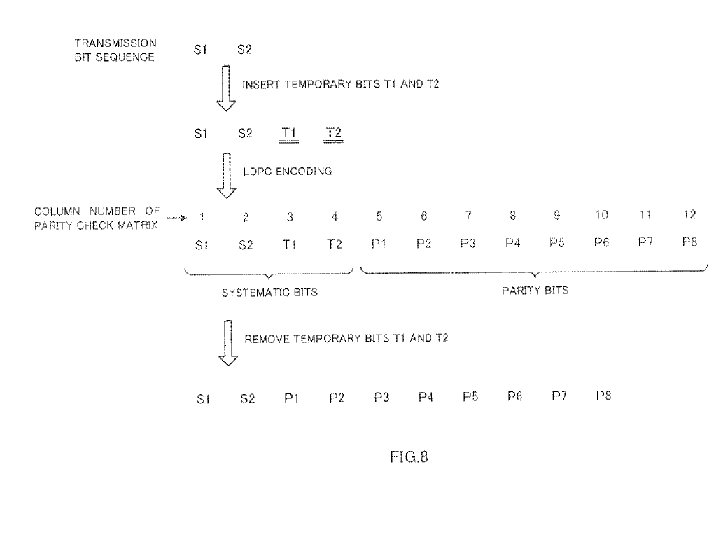

Then, temporary bit inserting section 101 selects the combination having the largest determination value, that is, selects the combination of the largest number of connections with a plurality of different check nodes, and, in a transmission bit sequence, inserts the temporary bits in the same positions as a plurality of systematic bit positions corresponding to the variable nodes belonging to that combination. That is, as shown in FIG. 8, in a 2-bit transmission sequence S1 and S2, temporary bit inserting section 101 inserts temporary bits T1 and T2 in the same positions as the systematic bit positions corresponding to variable node 3 and variable node 4 belonging to the combination (3, 4), whose determination value shown in FIG. 7 is eight, which is the largest, that is, inserts the temporary bits following the second bit S2 of the transmission bit sequence. By this means, temporary bit inserting section 101 can acquire a 4-bit sequence S1, S2, T1 and T2, which is subject to LDPC encoding. Then, in LDPC encoding section 102, LDPC encoding is performed on a 4-bit sequence S1, S2, T1 and T2, and a 12-bit LDPC codeword composed of four systematic bits of S1, S2, T1 and T2 and eight parity bits of P1 to P8 is acquired. Further, in temporary bit removing section 103, temporary bits T1 and T2 are removed from the 12-bit LDPC codeword and an 10-bit LDPC codeword is acquired.

Further, in the same method as in temporary bit inserting section 101, temporary bit removing section 103 specifies the positions to remove temporary bits from and the number of temporary bits to remove.

Further, padding section 205 of radio communication apparatus 200 of the receiving side (FIG. 5) specifies the systematic bit positions to pad the temporary bits in the same method as in temporary bit inserting section 101.

In this way, according to the present embodiment, in the case where a plurality of temporary bits are inserted, in a transmission bit sequence, a plurality of temporary bits are inserted in the same positions as the systematic bit positions corresponding to the variable nodes belonging to the combination having the largest number of connections with a plurality of different check nodes amongst a plurality of combinations of variable nodes, so that it is possible to pass high likelihoods, which a plurality of temporary bits have, to a large number of check nodes. Consequently, according to the present embodiment, it is possible to provide optimum error rate performances constantly even when a plurality of temporary bits are inserted.

In the case where there are a plurality of combinations in which all check nodes are connected, in a transmission bit sequence, a plurality of temporary bits may be inserted in the same positions as the systematic bit positions corresponding to the variable nodes belonging to the combination having the smallest number of the sum of connections with check nodes per variable node amongst a plurality of combinations connected with all check nodes.

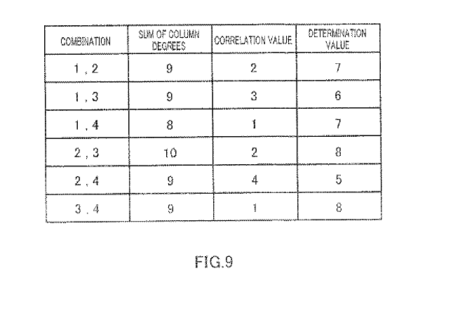

To be more specific, as described above, in all combinations of extracting two variable nodes as shown in FIG. 9, temporary bit inserting section 101 finds the determination value from the sum of column degrees and the correlation value. Here, there are two combinations of the combination (2, 3) and the combination (3, 4), whose determination values are the largest, which are eight, that is, there are two combinations in which all check nodes are connected. Temporary bit inserting section 101 compares the sum of the number of connections variable nodes belonging to the two combinations hold with check nodes, that is, compares the sum of column degrees in the combinations. Therefore, temporary bit inserting section 101 compares the sum of column degrees of the combination (2, 3), which is ten, and the sum of column degrees of the combination (3, 4), which is nine. Then, in a transmission bit sequence, temporary bit inserting section 101 inserts temporary bits in the same positions as the systematic bit positions corresponding to variable node 3 and variable node 4 belonging to the combination (3, 4) having the smallest sum of column degrees, which is nine.

The combination having the smallest sum of column degrees is the combination having the smallest correlation value in a plurality of combinations having the largest determination number. Therefore, by selecting the combination (3, 4) from the combination (2, 3) and the combination (3, 4) both having the determination value eight, it is possible to select a combination having the smallest number of overlapping connections variable nodes hold with the same check nodes in the combinations in which all check nodes are connected. Consequently, this selection makes it possible to connect all check nodes in the smallest number of connections with check nodes between variable nodes. Therefore, the likelihoods of temporary bits can be passed efficiently, so that it is possible to improve the effect of updating the likelihoods.

Further, the method of selecting combinations according to the present embodiment is an example, and, the present embodiment is not limited to the above method as long as the combinations having the largest number of connections with a plurality of different check nodes are selected amongst a plurality of combinations of variable nodes.

Embodiments of the present invention have been explained.

The temporary bit used in the embodiments may be 1 and 0 as long as the temporary bit is common between radio communication apparatus 100 of the transmitting side and radio communication apparatus 200 of the receiving side. For example, a temporary bit sequence may be a sequence composed of all 0s, a sequence composed of all is, or a common sequence composed of 1s and 0s. A temporary bit may be referred to as a “known bit.”

Further, although cases have been explained with the embodiments where the present invention is implemented in a FDD (Frequency Division Duplex) system, the present invention may be implemented in a TDD (Time Division Duplex) system. In the case of TLD system, the correlation between uplink channel characteristics and downlink channel characteristics is very high, so that radio communication apparatus 100 of the transmitting side can estimate received quality in radio communication apparatus 200 of the receiving side using signals from radio communication apparatus 200 of the receiving side. Therefore, in the case of TDD system, radio communication apparatus 200 of the receiving side may not report channel quality by CQI and radio communication apparatus 100 of the transmitting side may estimate channel quality.

Further, the parity check matrix shown in FIG. 2 is an example, and a parity check matrix utilized to implement the present invention is not limited to the parity check matrix shown in FIG. 2.

Further, the coding rate set in control section 111 of radio communication apparatus 100 of the transmitting side is not limited to coding rates to be determined according to channel quality, and, may be a fixed rate.

Further, although, with the present embodiments, SINR is estimated as channel quality, the SNR, SIR, CINR, received power, interference power, bit error rate, throughput, MCS that achieves a predetermined error rate, and so on may be estimated as channel quality. Further, a CQI may be referred to as “CSI (Channel State Information).”

Further, in mobile communication systems, radio communication apparatus 100 of the transmitting side may be provided in a radio communication base station apparatus and radio communication apparatus 200 of the receiving side may be provided in a radio communication mobile station apparatus. Further, radio communication apparatus 100 of the transmitting side may be provided in a radio communication mobile station apparatus and radio communication apparatus 200 of the receiving side may be provided in a radio communication base station apparatus. By this means, it is possible to realize a radio communication base station apparatus and radio communication mobile station apparatus providing an advantage as described above.

Further, a radio communication mobile station apparatus may be referred to as a “UE,” and a radio communication base station apparatus may be referred to as a “Node B.”

Further, although cases have been described with the above embodiment as examples where the present invention is configured by hardware, the present invention can also be realized by software.

Each function block employed in the description of each of the aforementioned embodiments may typically be implemented as an LSI constituted by an integrated circuit. These may be individual chips or partially or totally contained on a single chip. “LSI” is adopted here but this may also be referred to as “IC,” “system LSI,” “super LSI,” or “ultra LSI” depending on differing extents of integration.

Further, the method of circuit integration is not limited to LSIs, and implementation using dedicated circuitry or general purpose processors is also possible. After LSI manufacture, utilization of a programmable FPGA (Field Programmable Gate Array) or a reconfigurable processor where connections and settings of circuit cells within an LST can be reconfigured is also possible.

Further, if integrated circuit technology comes out to replace LSI's as a result of the advancement of semiconductor technology or a derivative other technology, it is naturally also possible to carry out function block integration using this technology. Application of biotechnology is also possible.

The disclosure of Japanese Patent Application No. 2007-012676, filed on Jan. 23, 2007, including the specification, drawings and abstract, is incorporated herein by reference in its entirety.

### INDUSTRIAL APPLICABILITY

The present invention is applicable to, for example, mobile communication systems.

1. A radio communication apparatus of a transmitting side that performs low density parity check encoding using a parity check matrix, comprising:
an inserting section that inserts, in a first bit sequence, a temporary bit in a same position as a systematic bit position corresponding to a variable node having a largest number of connections with check nodes in a Tanner graph that corresponds to the parity check matrix, to generate a second bit sequence;
an encoding section that performs low density parity check encoding using the parity check matrix for the second bit sequence, to acquire a codeword composed of a systematic bit and a party bit; and
a removing section that removes the temporary bit in the codeword.

2. The radio communication apparatus according to claim 1 wherein the inserting section determines a number of temporary bits to insert based on a difference between a first coding rate of the low density parity check encoding and a second coding rate according to channel quality.

3. The radio communication apparatus according to claim 1, wherein, when the inserting section inserts a plurality of temporary bits, the inserting section inserts, in the first bit sequence, the plurality of temporary bits in the same positions as a plurality of systematic bit positions corresponding to variable nodes belonging to a combination having the largest number of connections with a plurality of different check nodes amongst a plurality of combinations of variable nodes.

4. The radio communication apparatus according to claim 3, wherein, when there are a plurality of combinations in which all check nodes are connected, the inserting section inserts, in the first bit sequence, the plurality of temporary bits in the same positions as the plurality of systematic bit positions corresponding to the variable nodes belonging to the combination having a smallest sum of connections with check nodes per variable node amongst a plurality of combinations of variable nodes.

5. A radio communication apparatus of a receiving side comprising:
a padding section that pads, in a first received data, a temporary bit in a same position as a systematic bit position corresponding to a variable node having a largest number of connections with check nodes in a Tanner graph that corresponds to a parity check matrix for low density parity check encoding, to generate a second received data; and
a decoding section that performs low density parity check decoding using the parity check matrix for the second received data, to acquire a decoded bit sequence.

6. The radio communication apparatus according to claim 1, wherein the radio communication apparatus comprises a radio communication base station apparatus or a radio communication mobile station apparatus.

7. The radio communication apparatus according to claim 5, wherein the radio communication apparatus comprises a radio communication base station apparatus or a radio communication mobile station apparatus.

8. A temporary bit inserting method comprising:
in a bit sequence to be subject to low density parity check encoding, inserting a temporary bit in a same position as a systematic bit position corresponding to a variable node having a largest number of connections with check nodes in a Tanner graph that corresponds to a parity check matrix for the low density parity check encoding.
